(19) United States
(12) Patent Application Publication
(10) Pub. No.: US 2025/0293047 A1
(43) Pub. Date: Sep. 18, 2025

(54) SEMICONDUCTOR DEVICE AND METHOD OF REPAIRING WAFER

(71) Applicant: Hon Young Semiconductor Corporation, Hsinchu City (TW)

(72) Inventors: Juin-Ming WU, Hsinchu City (TW); Chun-Yuan CHOU, Hsinchu City (TW)

(21) Appl. No.: 18/659,004

(22) Filed: May 9, 2024

(30) Foreign Application Priority Data
Mar. 14, 2024 (TW) 113109544

(51) Int. Cl. H01L 21/324; H01L 21/04; H01L 29/16

(52) U.S. Cl. CPC H01L 21/324; H01L 21/0445; H10D 62/8325

(57) ABSTRACT

A method of repairing a wafer includes grinding a wafer to forming a damage layer at a surface of the wafer, performing a first annealing process to convert a lower portion of the damage layer into a regrown layer, in which the regrown layer is over the wafer, forming a metal layer over the damage layer, and performing a second annealing process to convert the damage layer and the metal layer into an alloy layer, wherein the alloy layer is over the regrown layer.

### CROSS-REFERENCE TO RELATED APPLICATION

This application claims priority to Taiwan Application Serial Number 113109544, filed Mar. 14, 2024, which is herein incorporated by reference in its entirety.

### BACKGROUND

### Field of Invention

The present invention relates to a semiconductor device and a method of repairing a wafer.

### Description of Related Art

Silicon carbide devices are a kind of common semiconductor devices, and have advantages of high band gap, high thermal conductivity and high breakdown voltage. The resistance of the silicon carbide device may be composed of the resistance of components in the device, such as the resistance of contact, channel, gate, JFET region and substrate. In order to lower the resistance of the substrate, the back side of the wafer is grinded to reduce the thickness of the wafer after the formation of the integrated circuit at the front side of the wafer. However, warpage issue may arise during grinding the wafer, which is not beneficial to subsequent processes of the wafer.

### SUMMARY

Some embodiments of the present disclosure provide a method of repairing a wafer including grinding a wafer to forming a damage layer at a surface of the wafer, performing a first annealing process to convert a lower portion of the damage layer into a regrown layer, in which the regrown layer is over the wafer, forming a metal layer over the damage layer, and performing a second annealing process to convert the damage layer and the metal layer into an alloy layer, wherein the alloy layer is over the regrown layer.

In some embodiments, the first annealing process is an ultraviolet laser annealing process.

In some embodiments, the damage layer is an amorphous layer.

In some embodiments, the wafer has a first crystal structure, the regrown layer has a second crystal structure, and the second crystal structure is different from the first crystal structure.

In some embodiments, a temperature of the first annealing process is between 900 degree Celsius and 1300 degree Celsius.

In some embodiments, a portion of the damage layer is not converted into the alloy layer during performing the second annealing process, and the damage layer is between the alloy layer and the regrown layer after the second annealing process.

In some embodiments, a thickness of the portion of the damage layer is less than a thickness of the regrown layer.

In some embodiments, a portion of the damage layer is not converted into the regrown layer during performing the first annealing process, and the damage layer is between the wafer and the regrown layer after the first annealing process.

In some embodiments, a thickness of the portion of the damage layer is less than a thickness of the regrown layer.

In some embodiments, a ratio of a thickness of the regrown layer to a thickness of the damage layer is between 0.5 and 1 after the first annealing process.

Some embodiments of the present disclosure provide a silicon carbide wafer, a crystalline silicon carbide layer and an alloy layer. The silicon carbide wafer has a first crystal structure. The crystalline silicon carbide layer is over the silicon carbide wafer. The crystalline silicon carbide layer has a second crystal structure, and the first crystal structure of the silicon carbide wafer is different from the second crystal structure of the crystalline silicon carbide layer. The alloy layer is over the crystalline silicon carbide layer.

In some embodiments, the alloy layer is a metal silicide layer.

In some embodiments, the semiconductor device further includes an amorphous silicon carbide layer between the silicon carbide wafer and the crystalline silicon carbide layer.

In some embodiments, a thickness of the amorphous silicon carbide layer is less than a thickness of the crystalline silicon carbide layer.

In some embodiments, the amorphous silicon carbide layer is in contact with the crystalline silicon carbide layer.

In some embodiments, the semiconductor device further includes an amorphous silicon carbide layer between the alloy layer and the crystalline silicon carbide layer.

In some embodiments, a thickness of the amorphous silicon carbide layer is less than a thickness of the crystalline silicon carbide layer.

In some embodiments, the amorphous silicon carbide layer is in contact with the crystalline silicon carbide layer.

In some embodiments, the alloy layer is in contact with the crystalline silicon carbide layer.

In some embodiments, the silicon carbide wafer is in contact with the crystalline silicon carbide layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1-5 illustrate cross-section views of a method of repairing a wafer in some embodiments of the present disclosure.

FIG. 6 illustrates a cross-section view of a method of repairing a wafer in some other embodiments of the present disclosure.

FIG. 7 illustrates a cross-section view of a method of repairing a wafer in some other embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

Some embodiments of the present disclosure provide a method of repairing a damage layer of a wafer. The damage layer of the wafer results from a wafer thinning process. Specifically, an annealing process is used in the present disclosure to convert amorphous structures in the damage layer into crystal structures to eliminate cracks formed by the wafer thinning process.

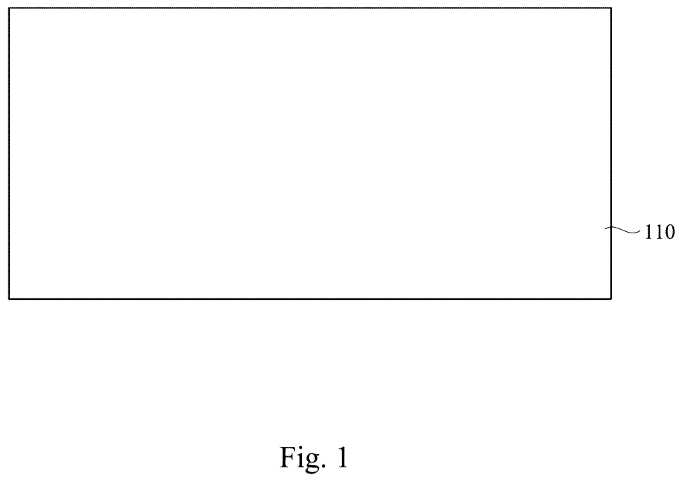

FIGS. 1-5 illustrate cross-section views of a method of repairing a wafer 110 in some embodiments of the present disclosure. Referring to FIG. 1, a wafer 110 is provided. The wafer 110 may be any suitable wafer. In some embodiments, the wafer 110 may be a silicon carbide wafer, and the wafer 110 has a first crystal structure.

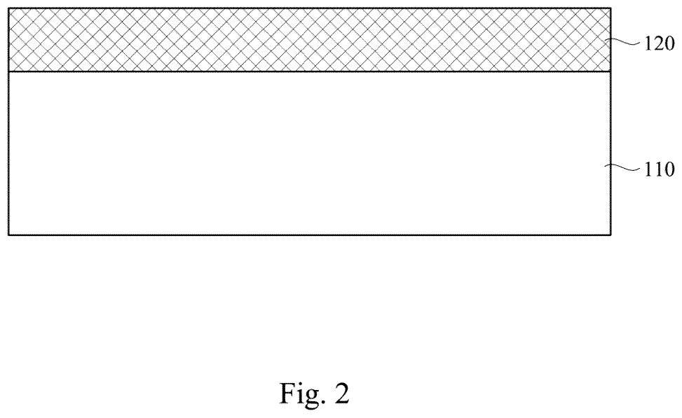

Referring to FIG. 2, the wafer 110 is grinded to form a damage layer 120 at a surface of the wafer 110. The purpose of grinding the wafer 110 is to reduce the thickness of the wafer 110 to the required thickness in subsequent processes. In some embodiments, after grinding the wafer 110, the thickness of the wafer 110 is reduced to less than half of the original thickness of the wafer 110. In some embodiments, grinding wheels or other suitable method may be used to grind the wafer 110. During grinding the wafer 110, the tools in the grinding process may cause damage to the surface of the wafer 110. For example, the stress of the surface of the wafer 110 is uneven, and thus the damage layer 120 is formed at the surface of the wafer 110. The crystal structure of the original wafer 110 is destroyed in the damage layer 120, such that the damage layer 120 has cracks in vertical direction. Therefore, the damage layer 120 does not have crystal structure. That is, the damage layer 120 is an amorphous layer. In some embodiments where the wafer 110 is silicon carbide, the damage layer 120 is an amorphous silicon carbide layer. In some embodiments, the thickness of the damage layer 120 is between 300 nm and 700 nm. It is noted that since the damage layer 120 is formed due to uneven stress, although the damage layer 120 is illustrated as flat layer in FIG. 2, the thickness of the damage layer 120 is not uniform actually. When the damage layer 120 is existed, the wafer 110 tends to have warpage issue. The warped wafer 110 may cause problems in the subsequent processes. For example, the warped wafer 110 may cause damage to other wafers 110 during transfer. When cutting warped wafer 110, the warped wafer 110 may not be cut into perfect shapes.

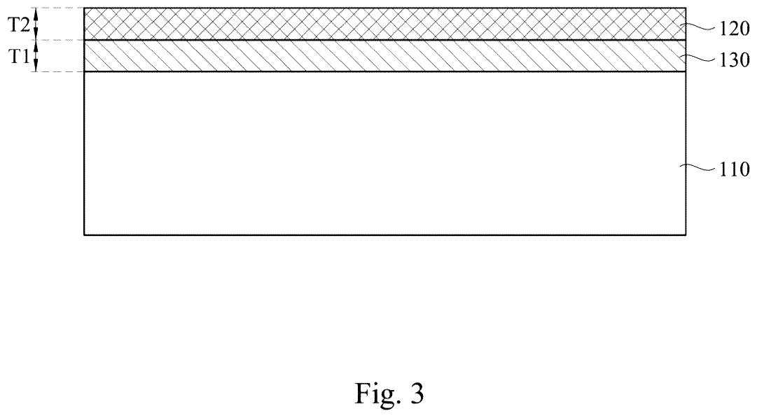

Referring to FIG. 3, a first annealing process is performed to convert a lower portion of the damage layer 120 into a regrown layer 130, and the regrown layer 130 is over the wafer 110. Specifically, the first annealing process is an ultraviolet laser annealing process. The ultraviolet laser annealing process can provide enough heat at shallow depths, and the ultraviolet laser is easily coupled with non-mirror surface (such as surface of the damage layer 120). Therefore, the ultraviolet laser annealing process is suitable for repairing the damage layer 120 at the surface of the wafer 110. In some embodiments, the energy of the ultraviolet laser is adjusted during performing the first annealing process, such that the ultraviolet laser is applied to the lower portion of the damage layer 120 (for example, at the depth at 600 nm to 700 nm). The heat provided by the first annealing process can repair the cracks at the lower portion of the damage layer 120, and the atoms in the lower portion of the damage layer 120 are rearranged to form a regrown layer 130 having a second crystal structure. The first crystal structure of the wafer 110 and the second crystal structure of the regrown layer 130 are different, and there is an observable boundary between the wafer 110 and the regrown layer 130. In some embodiments, a temperature of the first annealing process is between 900 degree Celsius and 1300 degree Celsius, and the temperature of the first annealing process (i.e. the melting temperature of the damage layer 120) is lower than the melting temperature of the wafer 110. Therefore, the temperature described above can repair the cracks in the damage layer 120, but do not damage the crystal structure of the wafer 110. Due to the limit of the heat transfer of the first annealing process, heat cannot transfer to the entire damage layer 120. Therefore, only the lower portion of the damage layer 120 is converted into the regrown layer 130 during the first annealing process. In some embodiments, a ratio of a thickness T1 of the regrown layer 130 to a thickness T2 of the damage layer 120 is between 0.5 and 1 after the first annealing process. It is noted that since the damage layer 120 is formed from the grinding process of the wafer 110, the regrown layer 130 is formed form the annealing process of the damage layer 120, so the damage layer 120, the regrown layer 130 and the wafer 110 are made of the same material. For example, the damage layer 120, the regrown layer 130 and the wafer 110 are all made of silicon carbide. The difference among the three lies in the crystal structure. For example, the wafer 110 has a first crystal structure, the regrown layer 130 has a second crystal structure, and the damage layer 120 has an amorphous structure. In some embodiments, the regrown layer 130 is also referred as a crystalline silicon carbide layer.

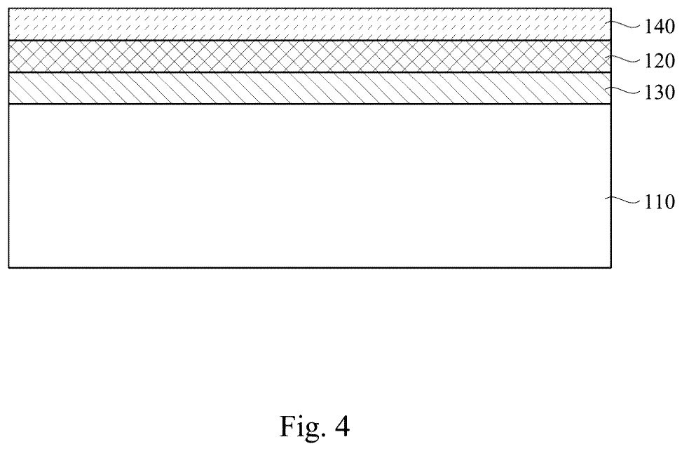

Referring to FIG. 4, a metal layer 140 is formed over the damage layer 120. Specifically, the metal layer 140 may include any suitable metal, such as nickel.

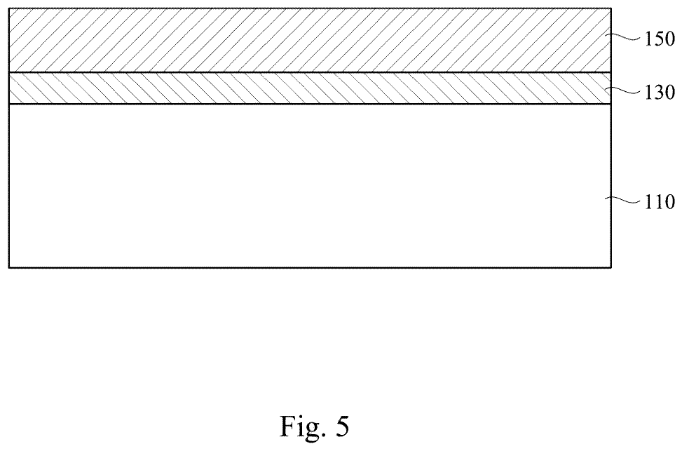

Referring to FIG. 5, a second annealing process is performed to convert the damage layer 120 and the metal layer 140 into an alloy layer 150, and the alloy layer 150 is over the regrown layer 130. Specifically, remaining damage layer 120 and the metal layer 140 over the damage layer 120 undergo reaction during the second annealing process to form the alloy layer 150. In some embodiments, the damage layer 120 is made of silicon carbide, and thus the alloy layer 150 may be metal silicide layer after the second annealing process. In some embodiments, the alloy layer 150 may contain carbon. Due to the limit of the heat transfer of the second annealing process, if the lower portion of the damage layer 120 is not converted into the regrown layer 130 in FIG. 3, the heat in the second annealing process does not transfer to the lower portion of the damage layer 120. The lower portion of the damage layer 120 cannot react with the metal layer 140 and be converted into the alloy layer 150, and thus the remaining damage layer 120 may still cause the warpage of the wafer 110. In the present disclosure, since the lower portion of the damage layer 120 is converted into the regrown layer 130 in FIG. 3, damage layer 120 will not exist after the damage layer 120 and the metal layer 140 are converted into the alloy layer 150. The warpage issue of the wafer 110 will be solved accordingly.

After forming the alloy layer 150, the semiconductor device may include a wafer 110, a regrown layer 130 and an alloy layer 150. The wafer 110 has a first crystal structure. The regrown layer 130 is over the wafer 110, the regrown layer 130 and the wafer 110 are made of the same material, and the regrown layer 130 has a second crystal structure. The first crystal structure of the wafer 110 is different from the second crystal structure of the regrown layer 130. In some embodiments, the regrown layer 130 and the wafer 110 are both made of silicon carbide, but the regrown layer 130 and the wafer 110 have different crystal structures. The alloy layer 150 is over the regrown layer 130. In some embodiments, the alloy layer 150 is in contact with the regrown layer 130, and the wafer 110 is in contact with the regrown layer 130. The alloy layer 150 may serve as the first metal layer (M1) over the surface of the wafer 110, and the subsequent processes may be performed over the alloy layer 150. For example, other metal layers are deposited over the alloy layer 150, and the wafer 110 is cut. If the warpage issue of the wafer 110 is solved, the subsequent processes may be smoothly performed. For example, when cutting the wafer 110, the wafer 110 can be cut into regular shapes.

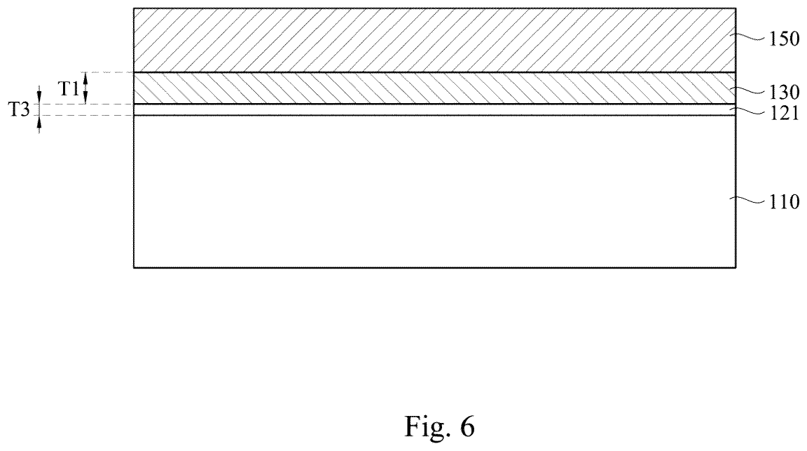

FIG. 6 illustrates a cross-section view of a method of repairing a wafer 110 in some other embodiments of the present disclosure. The semiconductor device in FIG. 6 is similar to the semiconductor device in FIG. 5. The difference is that the semiconductor device in FIG. 6 further includes a damage layer 121. The damage layer 121 is between the wafer 110 and the regrown layer 130, and the damage layer 121 is in contact with the wafer 110 and the regrown layer 130. In some embodiments, during the first annealing process (FIG. 3), a portion of the damage layer 120 is not converted into the regrown layer 130, and the portion of the damage layer 120 is under the regrown layer 130. After the first annealing process, the portion of the damage layer 120 is between the wafer 110 and the regrown layer 130. The portion of the damage layer 120 is referred to the damager layer 121. In some embodiments, when the damage layer 120 is an amorphous silicon carbide layer, the damage layer 121 is also an amorphous silicon carbide layer. The thickness T3 of the damage layer 121 is less than the thickness T1 of the regrown layer 130, so even if the damage layer 121 exists, the damage layer 120 is mainly converted into the regrown layer 130 or the alloy layer 150 after the second annealing process. Therefore, the present disclosure still can reduce the warpage issue of the wafer 110.

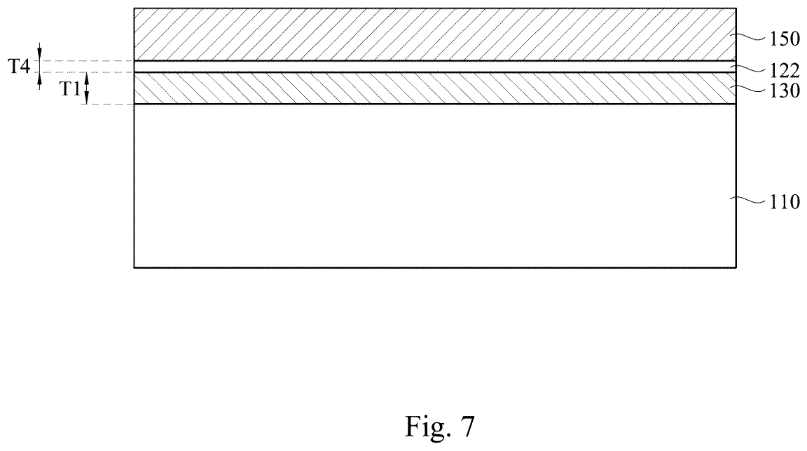

FIG. 7 illustrates a cross-section view of a method of repairing a wafer 110 in some other embodiments of the present disclosure. The semiconductor device in FIG. 7 is similar to the semiconductor device in FIG. 5. The difference is that the semiconductor device in FIG. 7 further includes a damage layer 122. The damage layer 122 is between the alloy layer 150 and the regrown layer 130, and the damage layer 122 is in contact with the alloy layer 150 and the regrown layer 130. In some embodiments, during the second annealing process (FIG. 5), a portion of the damage layer 120 is not converted into the alloy layer 150. After the second annealing process, the portion of the damage layer 120 is between the alloy layer 150 and the regrown layer 130. The portion of the damage layer 120 is referred to the damager layer 122. In some embodiments, when the damage layer 120 is an amorphous silicon carbide layer, the damage layer 122 is also an amorphous silicon carbide layer. The thickness T4 of the damage layer 122 is less than the thickness T1 of the regrown layer 130, so even if the damage layer 122 exists, the damage layer 120 is mainly converted into the regrown layer 130 or the alloy layer 150. Therefore, the present disclosure still can reduce the warpage issue of the wafer 110.

As mentioned above, some embodiments of the present disclosure may convert a portion of the damage layer into a regrown layer, and then the remaining damage layer reacts with a metal layer to form an alloy layer. As a result, after forming the alloy layer, the damage layer does not exist or barely exists. The warpage issue of the wafer is solved accordingly. When the warpage issue of the wafer is not significant, the subsequent processes of the wafer can be performed smoothly.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of repairing a wafer, comprising:
grinding the wafer to forming a damage layer at a surface of the wafer;
performing a first annealing process to convert a lower portion of the damage layer into a regrown layer, wherein the regrown layer is over the wafer;
forming a metal layer over the damage layer; and
performing a second annealing process to convert the damage layer and the metal layer into an alloy layer, wherein the alloy layer is over the regrown layer.

2. The method of claim 1, wherein the first annealing process is an ultraviolet laser annealing process.

3. The method of claim 1, wherein the damage layer is an amorphous layer.

4. The method of claim 1, wherein the wafer has a first crystal structure, the regrown layer has a second crystal structure, and the second crystal structure is different from the first crystal structure.

5. The method of claim 1, wherein a temperature of the first annealing process is between 900 degree Celsius and 1300 degree Celsius.

6. The method of claim 1, wherein a portion of the damage layer is not converted into the alloy layer during performing the second annealing process, and the damage layer is between the alloy layer and the regrown layer after the second annealing process.

7. The method of claim 6, wherein a thickness of the portion of the damage layer is less than a thickness of the regrown layer.

8. The method of claim 1, wherein a portion of the damage layer is not converted into the regrown layer during performing the first annealing process, and the damage layer is between the wafer and the regrown layer after the first annealing process.

9. The method of claim 8, wherein a thickness of the portion of the damage layer is less than a thickness of the regrown layer.

10. The method of claim 8, wherein a ratio of a thickness of the regrown layer to a thickness of the damage layer is between 0.5 and 1 after the first annealing process.

11. A semiconductor device, comprising:
a silicon carbide wafer having a first crystal structure;
a crystalline silicon carbide layer over the silicon carbide wafer, the crystalline silicon carbide layer having a second crystal structure; wherein the first crystal structure of the silicon carbide wafer is different from the second crystal structure of the crystalline silicon carbide layer; and
an alloy layer over the crystalline silicon carbide layer.

12. The semiconductor device of claim 11, wherein the alloy layer is a metal silicide layer.

13. The semiconductor device of claim 11, further comprising:
an amorphous silicon carbide layer between the silicon carbide wafer and the crystalline silicon carbide layer.

14. The semiconductor device of claim 13, wherein a thickness of the amorphous silicon carbide layer is less than a thickness of the crystalline silicon carbide layer.

15. The semiconductor device of claim 13, wherein the amorphous silicon carbide layer is in contact with the crystalline silicon carbide layer.

16. The semiconductor device of claim 11, further comprising:
an amorphous silicon carbide layer between the alloy layer and the crystalline silicon carbide layer.

17. The semiconductor device of claim 16, wherein a thickness of the amorphous silicon carbide layer is less than a thickness of the crystalline silicon carbide layer.

18. The semiconductor device of claim 16, wherein the amorphous silicon carbide layer is in contact with the crystalline silicon carbide layer.

19. The semiconductor device of claim 11, wherein the alloy layer is in contact with the crystalline silicon carbide layer.

20. The semiconductor device of claim 11, wherein the silicon carbide wafer is in contact with the crystalline silicon carbide layer.
